(19) United States
(12) Patent Application Publication
(10) Pub. No.: US 2024/0355840 A1
(43) Pub. Date: Oct. 24, 2024

(54) ARRAY SUBSTRATE AND MANUFACTURING METHOD THEREOF, AND DISPLAY PANEL

(71) Applicant: Guangzhou China Star Optoelectronics Semiconductor Display Technology Co., Ltd., Guangzhou (CN)

(72) Inventors: Peng SHU, Guangzhou (CN); Peng GAO, Guangzhou (CN); Rui FANG, Guangzhou (CN); Jiannan DAI, Guangzhou (CN)

(21) Appl. No.: 18/518,508

(22) Filed: Nov. 23, 2023

(30) Foreign Application Priority Data
Apr. 20, 2023 (CN) 202310433052.7

(51) Int. Cl. H01L 27/12

(52) U.S. Cl. CPC H01L 27/1259; H01L 27/124

(57) ABSTRACT

An array substrate includes a substrate, a first metal layer, a first insulating layer, an active layer, a first electrode, a second metal layer, a second insulating layer, and a second electrode. The first insulating layer covers the first metal layer. The active layer on the first insulating layer and overlaps a gate of the first metal layer. The first electrode on the first insulating layer is spaced apart from the active layer. A portion of the second metal layer is located on the active layer. The second metal layer includes a first metal electrode connected to the active layer and a second metal electrode which is separated from the first metal electrode, and connected to the active layer and the first electrode. The second insulating layer covers the second metal layer, the first electrode, and the active layer. The second electrode is disposed on the second insulating layer.

### CROSS REFERENCE TO RELATED APPLICATION

This application claims the priority of Chinese Patent Application No. 202310433052.7, entitled “ARRAY SUBSTRATE AND MANUFACTURING METHOD THEREOF, AND DISPLAY PANEL”, filed on Apr. 20, 2023, the disclosure of which is incorporated herein by reference in its entirety.

### FIELD OF THE DISCLOSURE

The present disclosure relates to a field of display technology, in particular to an array substrate and a manufacturing method thereof, and a display panel.

### BACKGROUND

Indium gallium zinc oxide (IGZO) is an amorphous oxide containing indium, gallium, and zinc, and has high mobility, and its carrier mobility is 20-30 times that of amorphous silicon. Indium gallium zinc oxide as an active layer can greatly increase a charging and discharging rate of a thin film transistor to a pixel electrode, the thin film transistor manufactured by it has a high on-state current and a low off-state current, which can be switched quickly, increase a response speed of a pixel, and achieve a faster refresh rate. At the same time, faster response also greatly increases a row scanning rate of pixels, making ultra-high resolution possible in liquid crystal displays. In addition, use of indium gallium zinc oxide can reduce a number of transistors. Since a reduction in a number of transistors increases a light transmittance of each pixel, an indium gallium zinc oxide display has a higher level of energy efficiency and higher efficiency.

However, manufacturing an indium gallium zinc oxide display currently requires a large number of photomasks, resulting in a higher manufacturing cost of the indium gallium zinc oxide display.

Therefore, how to reduce a number of photomasks required to manufacture an indium gallium zinc oxide display to reduce a manufacturing cost of indium gallium zinc oxide display is a technical problem that needs to be solved.

### SUMMARY

An objective of the present disclosure is to provide an array substrate and a manufacturing method thereof, and a display panel, to reduce a number of photomasks required to manufacture the array substrate, thereby reducing a number of photomasks required to manufacture the display panel.

In a first aspect, the present disclosure provides an array substrate, which comprises a substrate, a first metal layer, a first insulating layer, a first insulating layer, an active layer, a first electrode, a second metal layer, a second insulating layer, and a second electrode. The first metal layer is disposed on the substrate and comprising a gate. The first insulating layer covers the first metal layer and the substrate. The active layer is disposed on a surface of the first insulating layer away from the substrate and overlapping the gate. The first electrode is disposed on the surface of the first insulating layer away from the substrate and spaced apart from the active layer. At least a portion of the second metal layer is located on a side of the active layer away from the substrate and comprises a first metal electrode and a second metal electrode disposed at intervals. The first metal electrode is connected to the active layer, and the second metal electrode is connected to the active layer and the first electrode. The second insulating layer covers the second metal layer, the first electrode, and the active layer. The second electrode is disposed on a surface of the second insulating layer away from the substrate.

Optionally, the first electrode comprises a crystalline phase.

Optionally, a material of the first electrode is different from a material of the active layer.

Optionally, a material of the active layer comprises at least one of metal oxide, polysilicon, and amorphous silicon, and a material of the first electrode and a material of the second electrode comprise at least one of indium tin oxide and indium zinc oxide.

In a second aspect, the present disclosure provides a display panel which comprises an array substrate and a counter substrate disposed opposite to the array substrate. The array substrate comprises a substrate, a first metal layer, a first insulating layer, a first insulating layer, an active layer, a first electrode, a second metal layer, a second insulating layer, and a second electrode. The first metal layer is disposed on the substrate and comprising a gate. The first insulating layer covers the first metal layer and the substrate. The active layer is disposed on a surface of the first insulating layer away from the substrate and overlapping the gate. The first electrode is disposed on the surface of the first insulating layer away from the substrate and spaced apart from the active layer. At least a portion of the second metal layer is located on a side of the active layer away from the substrate and comprises a first metal electrode and a second metal electrode disposed at intervals. The first metal electrode is connected to the active layer, and the second metal electrode is connected to the active layer and the first electrode. The second insulating layer covers the second metal layer, the first electrode, and the active layer. The second electrode is disposed on a surface of the second insulating layer away from the substrate.

Optionally, the first electrode comprises a crystalline phase.

Optionally, a material of the first electrode is different from a material of the active layer.

Optionally, a material of the active layer comprises at least one of metal oxide, polysilicon, and amorphous silicon, and a material of the first electrode and a material of the second electrode comprise at least one of indium tin oxide and indium zinc oxide.

In a third aspect, the present disclosure provides a method for manufacturing an array substrate, which comprises: forming a first metal layer on a substrate, wherein the first metal layer comprises a gate; forming a first insulating layer covering the first metal layer and the substrate; forming a first electrode on a surface of the first insulating layer away from the substrate; forming an active layer on the surface of the first insulating layer away from the substrate, wherein the active layer overlaps the gate; forming a second metal layer, wherein the second metal layer comprises a first metal electrode and a second metal electrode disposed at intervals, the first metal electrode is located on a surface of the active layer away from the substrate, and the second metal electrode is connected to the active layer and the first electrode; forming a second insulating layer covering the second metal layer, the first electrode, and the active layer; and forming a second electrode on a surface of the second insulating layer away from the substrate.

Optionally, after the first electrode is formed on the surface of the first insulating layer away from the substrate, the active layer is formed on the surface of the first insulating layer away from the substrate.

Optionally, the forming the first electrode on the surface of the first insulating layer away from the substrate comprises: forming a first initial electrode on the surface of the first insulating layer away from the substrate; and crystallizing the first initial electrode to obtain the first electrode.

Optionally, the crystallizing the first initial electrode comprises: annealing the first initial electrode at a temperature of 200° C. to 250° C. to obtain the first electrode.

Optionally, a material of the active layer comprises at least one of metal oxide, polysilicon, and amorphous silicon, and a material of the first electrode comprises at least one of indium tin oxide and indium zinc oxide.

Since the active layer is disposed on the surface of the first insulating layer away from the substrate, the first electrode is disposed on the surface of the first insulating layer away from the substrate and is spaced apart from the active layer, and the second metal electrode is connected to the active layer and the first electrode, the first electrode and the active layer can be connected without via holes, thereby reducing a number of photomasks required for forming via holes, and thus reducing a number of photomasks required for manufacturing the array substrate.

### BRIEF DESCRIPTION OF DRAWINGS

FIG. 1 is a flowchart of manufacturing an array substrate according to an embodiment of the present disclosure.

FIG. 2A to FIG. 2F illustrate diagrams of a method of manufacturing the array substrate according to the embodiment of the present disclosure.

FIG. 3 is a schematic diagram of a display panel according to an embodiment of the present disclosure.

### DETAILED DESCRIPTION OF PREFERRED EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

The array substrate includes a substrate, a gate, a common electrode line, a gate insulating layer, an active layer, a source, a drain, a connecting electrode, a first passivation layer, a planarization layer, a common electrode, a second passivation layer and a pixel electrode. The common electrode line and the gate electrode are arranged on the substrate. The gate insulating layer covers the substrate, the common electrode line and the gate electrode. The gate insulation layer includes overlapping holes overlapping the common electrode lines. The active layer is disposed on the gate insulating layer and overlaps the gate. The source and drain electrodes are disposed on a surface of the active layer away from the substrate and include spaced apart source and drain electrodes. The overlapping electrode is disposed on the gate insulating layer and connected to the common electrode line through the overlapping hole. The first passivation layer covers the overlapping electrode, the source and drain electrodes and the gate insulating layer. The planarization layer covers the surface of the first passivation layer away from the source and the drain. The planarization layer includes a first via above the drain electrode. The common electrode is located on a surface of the planarization layer away from the first passivation layer. The common electrode is connected to the lap electrode. The second passivation layer covers the common electrode and the planarization layer. The pixel electrode is located on a surface of the second passivation layer away from the substrate. The pixel electrode passes through the first via hole and is connected to the drain electrode through a second via hole that penetrates the second passivation layer and the first passivation layer.

In some related arts, a gate is fabricated with a first photomask, an active layer is fabricated with a second photomask, an overlapping hole in a gate insulating layer is fabricated with a third photomask, a source electrode, a drain electrode, and an overlapping electrode are fabricated with a fourth photomask, a first via hole in a planarization layer is fabricated with a fifth photomask, a common electrode is fabricated with a sixth photomask, a second via hole is fabricated with a seventh photomask, and a pixel electrode is fabricated with an eighth photomask. Therefore, in the related arts, manufacturing an array substrate requires eight photomasks, and there is a problem of a large number of photomasks required.

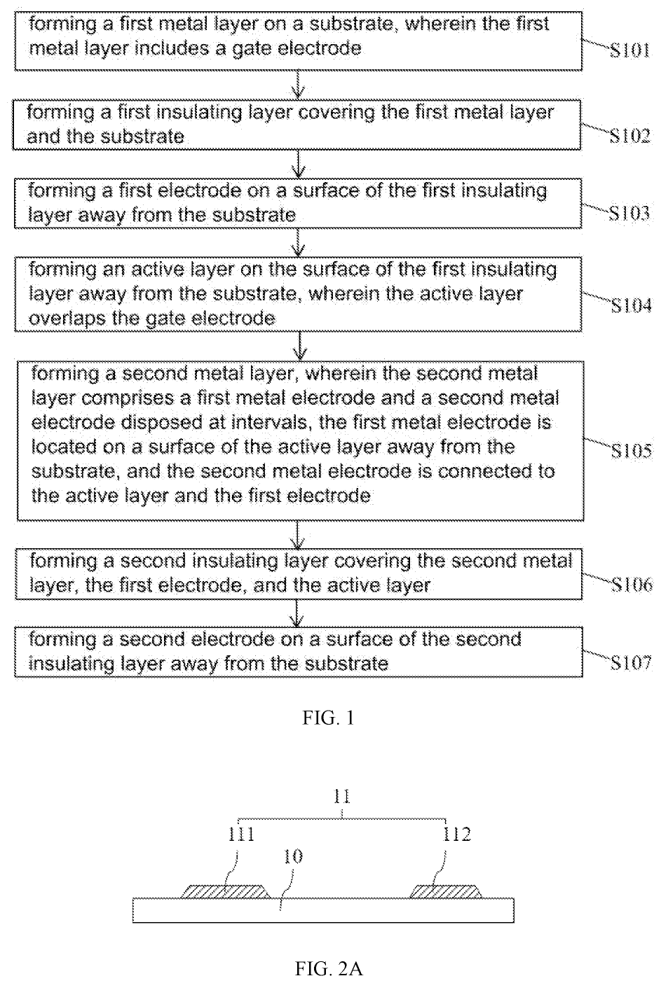

In view of that, please refer to FIG. 1, the present disclosure provides a method for manufacturing an array substrate, and the method comprises steps S101-S107.

At Step S101, a first metal layer on a substrate is formed.

At Step S102, a first insulating layer covering the first metal layer and the substrate is formed.

At Step S103, a first electrode on a surface of the first insulating layer away from the substrate is formed.

At Step S104, an active layer on the surface of the first insulating layer away from the substrate is formed. The active layer overlaps the gate.

At Step S105, a second metal layer is formed. The second metal layer comprises a first metal electrode and a second metal electrode disposed at intervals, the first metal electrode is located on a surface of the active layer away from the substrate, and the second metal electrode is connected to the active layer and the first electrode.

At Step S106, a second insulating layer covering the second metal layer, the first electrode, and the active layer is formed.

At Step S107, a second electrode on a surface of the second insulating layer away from the substrate is formed.

In the method for manufacturing the array substrate according to an embodiment of the present disclosure, the first electrode is formed on the surface of the first insulating layer away from the substrate, the active layer is formed on the surface of the first insulating layer away from the substrate, the second metal layer is formed, and the second metal layer comprises the first metal electrode and the second metal electrode disposed at intervals. The second metal electrode is connected to the active layer and the first electrode, so that connection between the active layer and the first electrode does not require via holes, thereby reducing a number of photomasks required for forming via holes, and thus reducing a number of photomasks required for manufacturing the array substrate.

Moreover, compared with the related arts, forming the first electrode on the surface of the first insulating layer away from the substrate is conducive to omitting a planarization layer and a passivation layer. While film layers are omitted to reduce a manufacturing cost of the array substrate, a number of photomasks required for forming via holes in the planarization layer is also omitted. In addition, omitting the planarization layer and the passivation layer also helps to reduce a number of deep holes in the array substrate, thereby increasing an overlapping yield of via holes in the array substrate.

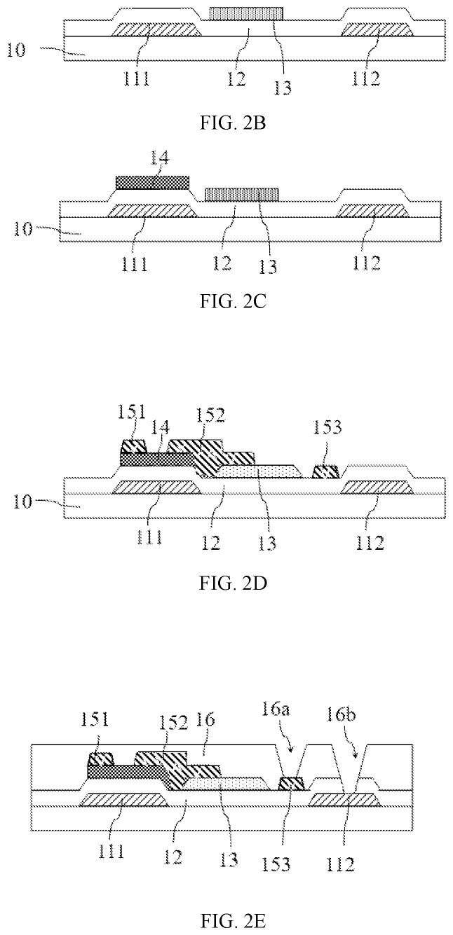

In some embodiments, as shown in FIG. 2A, the step of forming the first metal layer on the substrate is performed by forming a first metal layer 11 on a substrate 10. The first metal layer 11 comprises a gate 111 and a common electrode line 112 disposed at intervals.

A material of the first metal layer 11 may be one or a combination of molybdenum (Mo), titanium (Ti), aluminum (Al), and copper (Cu).

The first metal layer 11 is formed by physical vapor deposition, a photolithography process, and the like. Formation of the first metal layer 11 requires a first photomask. The photolithography process comprises a yellow light process, a wet etching process, a photoresist stripping process, and the like.

As shown in FIG. 2B, the step of forming the first insulating layer covering the first metal layer and the substrate is performed by forming a first insulating layer 12 covering the gate 111, the common electrode line 112, and the substrate 10.

Exemplarily, the first insulating layer 12 is formed by chemical vapor deposition.

The first insulating layer 12 comprises a silicon oxide (SiOₓ) layer, a silicon nitride (SiNₓ) layer, or a composite layer composed of a silicon oxide layer and a silicon nitride layer.

Please refer to FIG. 2B and FIG. 2C, a first electrode 13 is formed on a surface of the first insulating layer 12 away from the substrate 10, and then an active layer 14 is formed on the surface of the first insulating layer 12 away from the substrate 10.

After the first electrode 13 is formed on the surface of the first insulating layer 12 away from the substrate 10, the active layer 14 is formed on the surface of the first insulating layer 12 away from the substrate 10, which can reduce an impact of a manufacturing process of the first electrode 13 on the active layer 14.

Please refer to FIG. 2B, the step of forming the first electrode 13 on the surface of the first insulating layer 12 away from the substrate 12 is performed by forming a first initial electrode (not shown) on the surface of the first insulating layer away from the substrate, and crystallizing the first initial electrode to obtain the first electrode 13.

The first initial electrode is crystallized to obtain the first electrode 13, so that the first electrode 13 has a crystalline phase. The crystalline phase has good stability and chemical corrosion resistance, which reduces damage to the first electrode 13 caused by a manufacturing process of the active layer 14, in particular, reduces damage to the first electrode 13 caused by an etching liquid used to form the active layer 14.

The first initial electrode has an amorphous phase.

The step of crystallizing the first initial electrode is performed by annealing the first initial electrode at a temperature of 200° C. to 250° C. to obtain the first electrode 13.

The annealing temperature is 200° C., 220° C., 230° C., 240° C. or 250° C.

The first electrode 13 is a pixel electrode, but not limited thereto. The first electrode 13 may also be a common electrode.

Exemplarily, the first electrode 13 is formed by physical vapor deposition. Formation of the first electrode 13 requires a second photomask.

A material of the first electrode 13 comprises at least one of indium tin oxide and indium zinc oxide, so that the first electrode 13 has good electrical conductivity, which ensures that a strong electric field is formed between the first electrode 13 and the second electrode 17.

Please refer to FIG. 2C, the active layer 14 is formed on the surface of the first insulating layer 12 away from the substrate 10, the active layer 14 overlaps the gate 111, and the active layer 14 is spaced apart from the first electrode 13.

A material of the active layer 14 comprises at least one of metal oxide, polysilicon, and amorphous silicon.

The material of the active layer 14 and the material of the first electrode 13 both comprise metal oxide, and the material of the active layer 14 is different from the material of the first electrode 13.

The material of the active layer 14 comprises metal oxide, and the metal oxide comprises, but is not limited to, indium gallium zinc oxide.

When the materials of the active layer 14 and the first electrode 13 both comprise metal oxide and are different, etching solutions used to form the active layer 14 and the first electrode 13 will tend to be same, for example, both comprise nitric acid. When the active layer 14 and the first electrode 13 are formed on the first insulating layer 12 in steps, formation processes of the active layer 14 and the first electrode 13 may affect each other.

By first forming the first electrode 13 comprising the crystalline phase, a corrosive effect of the etching solution for forming the active layer 14 on the first electrode 13 is reduced.

Exemplarily, the active layer 14 is formed by a physical vapor deposition, a photolithography process, and the like. Formation of the active layer 14 requires a third photomask.

Please refer to FIG. 2D, a second metal layer is formed, and the second metal layer comprises a first metal electrode 151, a second metal electrode 152, and an overlapping electrode 153 disposed at intervals. The first metal electrode 151 is located on a surface of the active layer 14 away from the substrate 10, the second metal electrode 152 is connected to the active layer 14 and the first electrode 13, and the overlapping electrode 153 and the first electrode 13 are disposed at intervals.

The second metal electrode 152 extends from the active layer 14 through the first insulating layer 12 to the first electrode 13, so that connection between the active layer 14 and the first electrode 13 does not require via holes, thereby reducing a number of photomasks required for forming via holes.

The second metal layer is formed by physical vapor deposition, a photolithography process, and the like. Formation of the second metal layer requires a fourth photomask.

Please refer to FIG. 2E, the forming the second insulating layer covering the second metal layer, the first electrode, and the active layer comprises: forming a second insulating layer 16 covering the second metal layer, the first electrode 13, and the active layer 14, and forming a first via hole 16a and a second via hole 16b, wherein the first via hole 16a overlaps the overlapping electrode 153 and penetrates the second insulating layer 16. The second via hole 16b overlaps the common electrode line 112 and penetrates the second insulating layer 16 and the first insulating layer 12.

The second insulating layer 16 is formed by chemical vapor deposition, a photolithography process, and the like. The first via hole 16a and the second via hole 16b with different depths are formed with a fifth photomask, which reduces the number of photomasks.

A material of the second insulating layer 16 comprises a silicon oxide (SiOₓ) layer, a silicon nitride (SiNₓ) layer, or a composite layer composed of a silicon oxide layer and a silicon nitride layer.

Please refer to FIG. 2F, the forming the second electrode on the surface of the second insulating layer away from the substrate comprises: forming a second electrode 17 on a surface of the second insulating layer 16 away from the substrate 10. The second electrode 17 is connected to the overlapping electrode 153 through the first via hole 16a. The second electrode 17 is connected to the common electrode line 112 through the second via hole 16b.

The second electrode 17 is a common electrode, but not limited thereto. When the first electrode 13 may also be a common electrode, the second electrode 17 may also be a pixel electrode.

Exemplarily, the second electrode 17 comprises a plurality of slits.

The second electrode 17 is formed by physical vapor deposition, a photolithography process, and the like. Formation of the second electrode 17 requires a sixth photomask.

A material of the second electrode 17 comprises at least one of indium tin oxide and indium zinc oxide, so that the second electrode 17 has good electrical conductivity. Specifically, the material of the second electrode 17 comprises indium tin oxide.

It can be seen that the above method for manufacturing the array substrate requires six photomasks, which is two fewer than the related arts.

The array substrate manufactured by the above method for manufacturing the array substrate will be described below with reference to FIG. 2F.

An array substrate 100 comprises a substrate 10, a first metal layer, a first insulating layer 12, an active layer 14, a first electrode 13, a second metal layer, a second insulating layer 16, and a second electrode 17.

The first metal layer is disposed on the substrate 10. The first metal layer comprises a gate 111 and a common electrode line 112 disposed at intervals.

Exemplarily, a material of the first metal layer may be one or a combination of molybdenum (Mo), titanium (Ti), aluminum (Al), and copper (Cu).

The first insulating layer 12 covers the first metal layer and the substrate 10.

The first insulating layer 12 comprises a silicon oxide (SiOₓ) layer, a silicon nitride (SiNₓ) layer, or a composite layer composed of a silicon oxide layer and a silicon nitride layer.

The active layer 14 is disposed on a surface of the first insulating layer 12 away from the substrate 10 and overlaps the gate 111.

A material of the active layer 14 comprises at least one of metal oxide, polysilicon, and amorphous silicon.

The material of the active layer 14 and a material of the first electrode 13 both comprise metal oxide, and the material of the active layer 14 is different from the material of the first electrode 13.

The material of the active layer 14 comprises metal oxide, and the metal oxide comprise, but is not limited to, indium gallium zinc oxide.

The first electrode 13 is disposed on the surface of the first insulating layer 12 away from the substrate 10, and is spaced apart from the active layer 14.

The first electrode 13 comprises a crystalline phase, which reduces a corrosive effect of the etching solution for forming the active layer 14 on the first electrode 13.

The material of the first electrode 13 comprises at least one of indium tin oxide and indium zinc oxide, so that the first electrode 13 has good electrical conductivity, which ensures that a strong electric field is formed between the first electrode 13 and the second electrode 17.

At least a portion of the second metal layer is located on a side of the active layer 14 away from the substrate 10, and the second metal layer comprises a first metal electrode 151, a second metal electrode 152, and an overlapping electrode 153 disposed at intervals. The first metal electrode 151 is located on a surface of the active layer 14 away from the substrate 10, the second metal electrode 152 is connected to the active layer 14 and the first electrode 13, and the overlapping electrode 153 is disposed on the first insulating layer 12 and is spaced apart from the first electrode 13.

In some embodiments, the second metal electrode 152 extends from the active layer 14 through the first insulating layer 12 to the first electrode 13, so that connection between the active layer 14 and the first electrode 13 does not require via holes, thereby reducing a number of photomasks required for forming via holes.

A material of the second metal layer comprises one or a combination of molybdenum (Mo), titanium (Ti), aluminum (Al), and copper (Cu).

The second insulating layer 16 covers the second metal layer, the first electrode 13, and the active layer 14. The second insulating layer 16 comprises a first via hole 16a that penetrates the second insulating layer 16 and overlaps the overlapping electrode 153.

The array substrate 100 further comprises a second via hole 16b. The second via hole 16b overlaps the common electrode line 112 and penetrates the second insulating layer 16 and the first insulating layer 12.

Exemplarily, a material of the second insulating layer 16 comprises a silicon oxide (SiOₓ) layer, a silicon nitride (SiNₓ) layer, or a composite layer composed of a silicon oxide layer and a silicon nitride layer.

The second electrode 17 is disposed on a surface of the second insulating layer 16 away from the substrate 10. The second electrode 17 is connected to the overlapping electrode 153 through the first via hole 16a. The second electrode 17 is connected to the common electrode line 112 through the second via hole 16b.

The second electrode 17 is a common electrode, and the first electrode 13 is a pixel electrode. The first electrode 13 may also be a common electrode, and the second electrode 17 may be a pixel electrode.

A material of the second electrode 17 comprises at least one of indium tin oxide and indium zinc oxide, so that the second electrode 17 has good electrical conductivity. The material of the second electrode 17 comprises indium tin oxide.

In the array substrate according to an embodiment of the present disclosure, the active layer is disposed on the surface of the first insulating layer away from the substrate, the first electrode is disposed on the surface of the first insulating layer away from the substrate, and is spaced apart from the active layer, and the second metal electrode is connected to the active layer and the first electrode. This design allows the first electrode and the active layer to be connected without via holes, thereby reducing a number of photomasks required for forming via holes, and thus reducing a number of photomasks required for manufacturing the array substrate.

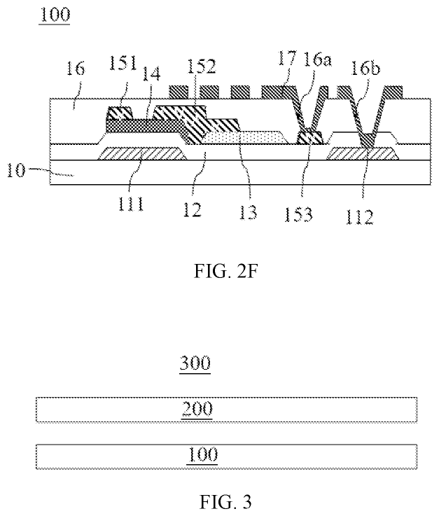

Please refer to FIG. 3, the present disclosure further provides a display panel 300. The display panel 300 is a liquid crystal display panel, an organic light-emitting diode display panel, a miniature light-emitting diode display panel, a sub-millimeter light-emitting diode display panel, and a quantum dot display panel.

The display panel 300 comprises a counter substrate 100 and an opposing substrate 200. The array substrate 100 and the counter substrate 200 are arranged opposite to each other.

The above description of the embodiments is only used to help understand technical solutions of the present disclosure and their core idea. Those of ordinary skill in the art should understand that they can still modify the technical solutions described in the above embodiments, or equivalently replace some of technical features in the technical solutions. These modifications or replacements do not make the essence of the corresponding technical solution out of the scope of the technical solution of each embodiment of the present disclosure.

What is claimed is:

1. An array substrate, comprising:
a substrate;
a first metal layer, disposed on the substrate and comprising a gate;
a first insulating layer, covering the first metal layer and the substrate;
an active layer, disposed on a surface of the first insulating layer away from the substrate and overlapping the gate;
a first electrode disposed on the surface of the first insulating layer away from the substrate and spaced apart from the active layer;
a second metal layer, wherein at least a portion of the second metal layer is located on a side of the active layer away from the substrate and comprises:
a first metal electrode, connected to the active layer; and
a second metal electrode, separated from the first metal electrode, and connected to the active layer and the first electrode;
a second insulating layer covering the second metal layer, the first electrode, and the active layer; and
a second electrode, disposed on a surface of the second insulating layer away from the substrate.

2. The array substrate according to claim 1, wherein the first electrode comprises a crystalline phase.

3. The array substrate according to claim 1, wherein a material of the first electrode is different from a material of the active layer.

4. The array substrate according to claim 1, wherein a material of the active layer comprises at least one of metal oxide, polysilicon, and amorphous silicon, and a material of the first electrode and a material of the second electrode comprise at least one of indium tin oxide and indium zinc oxide.

5. A display panel, comprising:
a counter substrate;
an array substrate, disposed opposite to the counter substrate, comprising:
a substrate;
a first metal layer, disposed on the substrate and comprising a gate;
a first insulating layer, covering the first metal layer and the substrate;
an active layer, disposed on a surface of the first insulating layer away from the substrate and overlapping the gate;
a first electrode disposed on the surface of the first insulating layer away from the substrate and spaced apart from the active layer;
a second metal layer, wherein at least a portion of the second metal layer is located on a side of the active layer away from the substrate and comprises:
a first metal electrode, connected to the active layer; and
a second metal electrode, separated from the first metal electrode, and connected to the active layer and the first electrode;
a second insulating layer, covering the second metal layer, the first electrode, and the active layer; and
a second electrode, disposed on a surface of the second insulating layer away from the substrate.

6. The display panel according to claim 5, wherein the first electrode comprises a crystalline phase.

7. The display panel according to claim 5, wherein a material of the first electrode is different from a material of the active layer.

8. The display panel according to claim 5, wherein a material of the active layer comprises at least one of metal oxide, polysilicon, and amorphous silicon, and a material of the first electrode and a material of the second electrode comprise at least one of indium tin oxide and indium zinc oxide.

9. A method for manufacturing an array substrate, comprising:
forming a first metal layer on a substrate, wherein the first metal layer comprises a gate;
forming a first insulating layer covering the first metal layer and the substrate;
forming a first electrode on a surface of the first insulating layer away from the substrate;
forming an active layer on the surface of the first insulating layer away from the substrate, wherein the active layer overlaps the gate;
forming a second metal layer, wherein at least a portion of the second metal layer is located on a side of the active layer away from the substrate and comprises: a first metal electrode connected to the active layer, and a second metal electrode, separated from the first metal electrode and connected to the active layer and the first electrode;
forming a second insulating layer covering the second metal layer, the first electrode, and the active layer; and
forming a second electrode on a surface of the second insulating layer away from the substrate.

10. The method according to claim 9, wherein after the first electrode is formed on the surface of the first insulating layer away from the substrate, the active layer is formed on the surface of the first insulating layer away from the substrate.

11. The method of claim 10, wherein the forming the first electrode on the surface of the first insulating layer away from the substrate comprises:
forming a first initial electrode on the surface of the first insulating layer away from the substrate; and
crystallizing the first initial electrode to obtain the first electrode.

12. The method according to claim 9, wherein the crystallizing the first initial electrode comprises:
annealing the first initial electrode at a temperature of 200° C. to 250° C. to obtain the first electrode.

13. The method of claim 9, wherein a material of the active layer comprises at least one of metal oxide, polysilicon, and amorphous silicon, and a material of the first electrode comprises at least one of indium tin oxide and indium zinc oxide.
